(19) United States
(12) Patent Application Publication
(10) Pub. No.: US 2009/0095981 A1
(43) Pub. Date: Apr. 16, 2009

(54) Complementary metal oxide semiconductor device and method of manufacturing the same

(75) Inventors: Dong-hun Kang, Yongin-si (KR); Sang-moon Lee, Suwon-si (KR); Joong S. Jeong, Seongnam-si (KR); Kwang-hyeon Baik, Suwon-si (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD.

(21) Appl. No.: 12/073,308

(22) Filed: Mar. 4, 2008

(30) Foreign Application Priority Data
Oct. 16, 2007 (KR) 10-2007-0104062

(51) Int. Cl. H01L 27/092; H01L 21/8238

(52) U.S. Cl. 257/190; 438/199; 257/E21.632; 257/E27.062

(57) ABSTRACT

Provided are a complementary metal oxide semiconductor (CMOS) device and a method of manufacturing the same. The CMOS device comprises an epi-layer that may be formed on a substrate; a first semiconductor layer and a second semiconductor layer that may be formed on different regions of the epi-layer, respectively; and a PMOS transistor and a NMOS transistor that may be formed on the first and second semiconductor layers, respectively.

### PRIORITY STATEMENT

This application claims the priority under 35 U.S.C. §119 to Korean Patent Application No. 10-2007-0104062, filed on Oct. 16, 2007, in the Korean Intellectual Property Office, the entire contents of which are incorporated by reference.

### BACKGROUND

1. Field

Example embodiments relate to a semiconductor device and a method of manufacturing the same, and more particularly, to a complementary metal oxide semiconductor (CMOS) device and a method of manufacturing the same.

2. Description of the Related Art

As is well-known, metal oxide semiconductor (MOS) transistors are used in the field of electronic devices. In particular, complementary metal oxide semiconductor (CMOS) devices, in which a P-channel MOS (PMOS) transistor and an N-channel MOS (NMOS) transistor are formed together to operate complementarily, may be used in various kinds of electronic devices due to their many advantages, such as low power consumption, wide-range operation region, high noise margin, and the like.

As the need for higher operation speed, reduced size and reduced manufacturing cost of the electronic devices, such as memory devices, increases, research for increasing the operation speed and degree of integration of CMOS devices has been conducted.

In general, if the length of a channel is shortened, the degree of integration of the transistor is increased, while the amount of current flowing through the channel is also increased. However, if the length of the channel is less than a critical value, a short channel effect may occur. Specifically, a shortened channel length may cause the potential of a source and a channel to be influenced by the potential of a drain. Accordingly, it may be difficult to increase the operation speed and/or degree of integration of a transistor by shortening the length of the channel.

Thus, research has been conducted to increase the output current and/or switching performance of a transistor by increasing the carrier mobility of the channel. However, since conventional methods may use an expensive silicon on insulator (SIO) substrate, or a wafer bonding method, or the like, problems associated with manufacturing processes may be complicated and/or costly.

### SUMMARY

Example embodiments may provide a complementary metal oxide semiconductor (CMOS) device that may include a channel having a higher carrier mobility, which may be more easily manufactured at a lower manufacturing cost.

Example embodiments also may provide a method of manufacturing a CMOS device.

According to example embodiments, there may be provided a CMOS device, including: an epi-layer formed on a substrate; a first semiconductor layer and a second semiconductor layer that may be formed on different regions of the epi-layer, respectively; and a PMOS transistor and a NMOS transistor that may be formed on the first and second semiconductor layers, respectively.

The epi-layer may include a SiGe layer.

The first semiconductor layer may include a lower layer and an upper layer that may be sequentially stacked on the epi-layer, wherein the lower layer may be a layer in which a channel may be formed and the upper layer may be a capping layer.

The lower layer may include a compressive strained Ge layer or a compressive strained GaAs layer.

The capping layer may include a Si layer.

A thickness of the capping layer may be in a range of 3 to 100 nm.

The second semiconductor layer may include a tensile strained Si layer.

According to example embodiments, there may be provided a CMOS device, including: a first semiconductor layer and a second semiconductor layer that may be formed on different regions of a substrate, respectively; and a PMOS transistor and a NMOS transistor that may be formed on the first and second semiconductor layers, respectively, wherein the first semiconductor layer comprises a lower layer in which a channel may be formed and a capping layer may be formed on the lower layer, and the capping layer and the second semiconductor layer may be formed of the same material.

A SiGe layer may be formed on the substrate, and the first and second semiconductor layers may be formed on the SiGe layer.

The lower layer may include a compressive strained Ge layer or a compressive strained GaAs layer.

The second semiconductor layer may include a tensile strained Si layer.

A thickness of the capping layer may be in a range of 3 to 100 nm.

According to example embodiments, there may be provided a method of manufacturing a CMOS device, including: forming an epi-layer on a substrate; forming first and second semiconductor layers on first and second regions of the epi-layer, respectively; and forming PMOS and NMOS transistors on the first and second semiconductor layers, respectively.

The epi-layer may be formed of SiGe.

The first semiconductor layer may include a lower layer and an upper layer that may be sequentially stacked on the epi-layer, wherein the lower layer may be a layer in which a channel may be formed and the upper layer may be a capping layer.

Forming the first and second semiconductor layers on the first and second regions of the epi-layer, respectively may include: forming the lower layer on the first region; and forming the capping layer on the lower layer and forming the second semiconductor layer on the second region.

The second semiconductor layer and the capping layer may be formed of the same material.

The second semiconductor layer and the capping layer may be simultaneously formed.

The second semiconductor layer may include a tensile strained Si layer.

The lower layer may include a compressive strained Ge layer or a compressive strained GaAs layer.

The capping layer may be formed with a thickness in the range of 3 to 100 nm.

### BRIEF DESCRIPTION OF THE DRAWINGS

The above and other features and advantages of example embodiments will become more apparent by describing in detail example embodiments with reference to the attached drawings. The accompanying drawings are intended to depict example embodiments and should not be interpreted to limit the intended scope of the claims. The accompanying drawings are not to be considered as drawn to scale unless explicitly noted.

FIG. 1 is a cross-sectional view of a complementary metal oxide semiconductor (CMOS) device according to an example embodiment.

FIGS. 2A through 2E are cross-sectional views illustrating a method of manufacturing the CMOS device according to an example embodiment.

FIGS. 3A through 3C are cross-sectional views illustrating a method of manufacturing a CMOS device, according to another example embodiment.

### DESCRIPTION OF EXAMPLE EMBODIMENTS

Detailed example embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

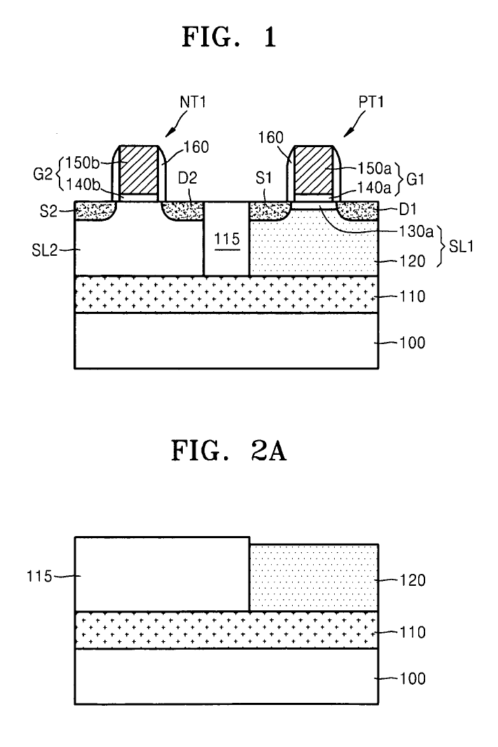

FIG. 1 is a cross-sectional view of a complementary metal oxide semiconductor (CMOS) device according to an example embodiment.

Referring to FIG. 1, an epi-layer 110 may be formed on a substrate 100 that may be a Si substrate, and the epi-layer 110 may be a SiGe layer, for example, a Si_{0.5}Ge_{0.5} layer. A first semiconductor layer SL1 and a second semiconductor layer SL2 may be formed on different regions of the epi-layer 110, respectively. An insulating layer 115 may be formed on the epi-layer 110 as a separation layer between the first semiconductor layer SL1 and the second semiconductor layer SL2.

The first semiconductor layer SL1 may include a lower layer 120 and an upper layer 130a that may be sequentially stacked on the epi-layer 110. The lower layer 120 may be a layer in which a channel may be formed, and the upper layer 130a may be a capping layer. The lower layer 120 may be a Ge layer or a GaAs layer and the upper layer 130a may be a Si layer. The second semiconductor layer SL2 may be a Si layer.

The lower layer 120 and the second semiconductor layer SL2 may be epitaxially grown on the epi-layer 110. The lower layer 120 may be a compressive strained layer, and the second semiconductor layer SL2 may be a tensile strained layer. The lower layer 120 and the second semiconductor layer SL2 may be compressive and tensile strained, respectively, according to a difference in a lattice constant of the material of the epi-layer 110, the lower layer 120 and the second semiconductor layer SL2. For example, since a lattice constant of SiGe (an example of the material of the epi-layer 110) is greater than that of Si (an example of the material of the second semiconductor layer SL2), the Si layer of the semiconductor layer SL2 grown on the SiGe layer of the epi-layer 110 may be tensile strained. Also, since the lattice constant of SiGe is less than that of Ge or GaAs (an example of the material of the lower layer 120), a Ge layer or GaAs layer of the lower layer 120 grown on the SiGe layer of the epi-layer 110 may be compressive strained. The epi-layer 110, the lower layer 120, and the second semiconductor layer SL2 need not be limited to the SiGe layer, the Ge layer or the GaAs layer, and the Si layer, respectively, as long as the epi-layer 110 may be formed of material having a lattice constant greater than that of the second semiconductor layer SL2 and less than that of the lower layer 120.

A PMOS transistor PT1 may be formed on the first semiconductor layer SL1, and a NMOS transistor NT1 may be formed on the second semiconductor layer SL2. The PMOS transistor PT1 may include a first gate G1, and a first source S1 and a first drain D1 that are formed at both sides of the first semiconductor layer SL1, such that the first gate G1 may be formed on the first semiconductor layer SL1 to be between the first source S1 and the first drain D1. In an example embodiment, the first source S1 and the first drain D1 may be p+ doping regions. The NMOS transistor NT1 may include a second gate G2, and a second source S2 and a second drain D2 that may be formed at both sides of the second semiconductor layer SL2, such that the second gate G2 may be formed on the second semiconductor layer SL2 to be between the second source S2 and the second drain D2. The second source S2 and the second drain D2 may be n+ doping regions. The first gate G1 may include a first gate insulating layer 140a and a first gate conductive layer 150a that may be sequentially stacked on the first semiconductor layer SL1, and the second gate G2 may include a second gate insulating layer 140b and a second gate conductive layer 150b that may be sequentially stacked on the second semiconductor layer SL2. The first gate conductive layer 150a and the second gate conductive layer 150b may either be formed of the same material, or not. An insulating spacer 160 may be further formed at both side walls of the first and second gates G1 and G2.

When the first gate insulating layer 140a is directly formed on the lower layer 120, the characteristics of the lower layer 120 may deteriorate, and thus, the upper layer 130a may be used to cap the lower layer 120 and reduce or prevent such deterioration. As described above, the upper layer 130a may be a Si layer and may not be used as a channel. That is, because when a predetermined or given voltage is applied to the first gate conductive layer 150a, a channel may be formed faster in the lower layer 120 than in the upper layer 130a. However, to easily form the channel in the lower layer 120, the upper layer 130a may be formed with a thickness in the range of 3 to 100 nm.

The lower layer 120 between the first source S1 and the first drain D1 may be a P-channel that functions as a path for holes. As described above, the lower layer 120 may be a Ge layer or a GaAs layer that may be a compressive strained layer. A movement speed of holes in the Ge layer or the GaAs layer may be faster than that of in a Si layer. A movement speed of holes in the compressive strained Ge layer or the compressive strained GaAs layer may be faster than that of a non-strained Ge layer or a non-strained GaAs layer. Accordingly, the P-channel of the lower layer 120 may have a higher hole mobility, and the PMOS transistor PT1 may have a higher movement speed and a higher switching performance.

The second semiconductor layer SL2 between the second source S2 and the second drain D2 may be a N-channel that functions as a path of electrons. The second semiconductor layer SL2 that may be used as the N-channel may be a tensile strained Si layer. A movement speed of electrons in the tensile strained Si layer is faster than that of an Si layer that is not tensile strained. In other words, the N-channel of the second semiconductor layer SL2 may have a higher electron mobility. Accordingly, the NMOS transistor NT1 may have a higher movement speed and a higher switching performance.

In addition, if Schottky barrier junctions are formed on the first source S1, the first drain D1, the second source S2, and the second drain D2, their contact resistance may be reduced. Therefore, the movement speed of the CMOS device may be further increased.

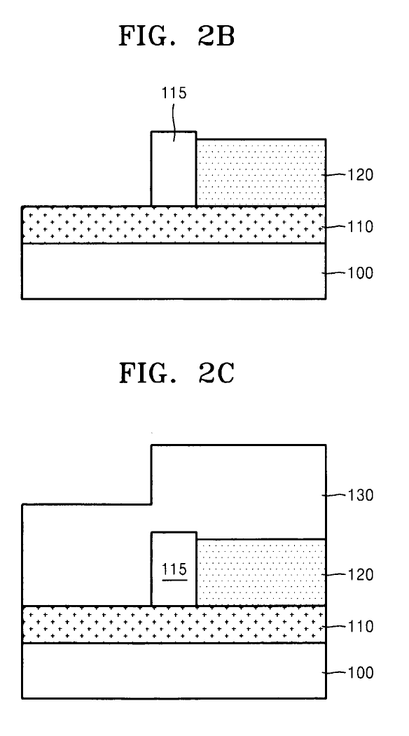

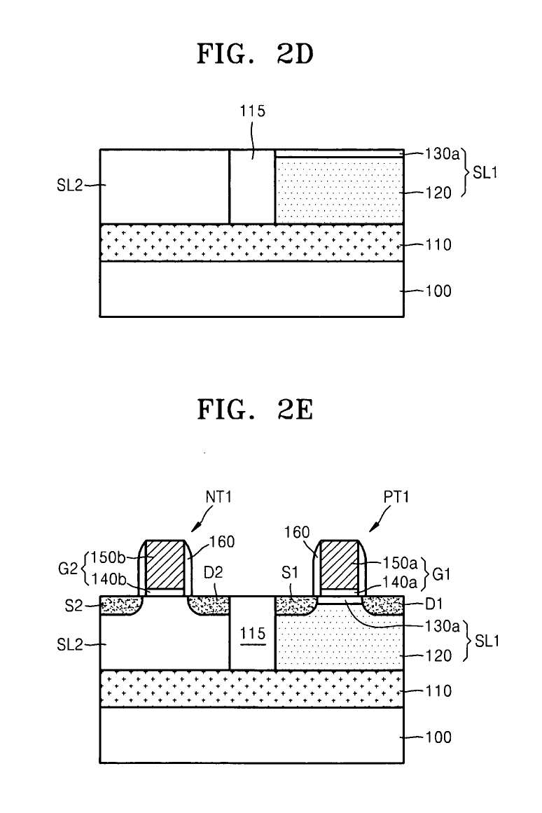

FIGS. 2A through 2E are cross-sectional views illustrating a method of manufacturing the CMOS device according to an example embodiment.

Referring to FIG. 2A, a epi-layer 110 may be formed on a substrate 100 that may be a Si substrate, and the epi-layer 110 may be a SiGe layer, for example, a Si_{0.5}Ge_{0.5} layer. An insulating layer 115 may be formed on a part of the epi-layer 110. The insulating layer 115 may be a silicon oxide layer or a silicon nitride layer. A lower layer 120 may be formed on the epi-layer 110 where the insulating layer is not formed. The lower layer 120 may be a Ge layer or a GaAs layer that may be epitaxially grown on the epi-layer 110, and may be a compressive strained layer. The lower layer 120 may be formed to be lower in height than the insulating layer 115.

Then, referring to FIG. 2B, a part of the insulating layer 115 may be removed so as to expose a part of the epi-layer 110, which may be spaced apart from the lower layer 120.

Referring to FIG. 2C, a semiconductor layer 130 may be formed on the lower layer 120 and the exposed epi-layer 110. The semiconductor layer 130 may be a Si layer and may be formed using an epitaxial growth method. In example embodiments, the semiconductor layer 130 may be formed on the insulating layer 115. The crystal structure of the semiconductor layer 130 formed on the insulating layer 115 may be different from that of the semiconductor layer 130 formed on the epi-layer 110 and the lower layer 120. For example, the semiconductor layer 130 formed on the insulating layer 115 may be amorphous or polycrystalline. However, if lateral growth of the semiconductor layer 130 is promoted by controlling conditions of the epitaxial growth process, the epitaxial semiconductor layer 130 may be formed on the insulating layer 115. Under different conditions, the semiconductor layer 130 may not be formed on the insulating layer 115.

The semiconductor layer 130 may be etched until the insulating layer 115 may be exposed by using the insulating layer 115 as an etch stop layer. The etching process may be performed using a chemical mechanical polishing (CMP) method. The result of the etching process is illustrated in FIG. 2D. Referring to FIG. 2D, the semiconductor layer SL2 remaining on the epi-layer 110 may be equivalent to the second semiconductor layer SL2 of FIG. 1, and the semiconductor layer 130a remaining on the lower layer 120 may be equivalent to the upper layer 130a of FIG. 1. Hereinafter, the semiconductor layer SL2 formed on the epi-layer 110 will be referred to as the second semiconductor layer SL2, and the semiconductor layer 130a formed on the lower layer 120 will be referred to as the upper layer 130a. The lower layer 120 and the upper layer 130a constitute the first semiconductor layer SL1 of FIG. 1.

Referring to FIG. 2E, a PMOS transistor PT1 may be formed on the first semiconductor layer SL1, and a NMOS transistor NT1 may be formed on the second semiconductor layer SL2. In example embodiments, after first and second gates G1 and G2 are formed on the first and second semiconductor layers SL1 and SL2 respectively, an insulating spacer 160 may be formed at both side walls of the first and second gates G1 and G2. The first gate G1 may include a first gate insulating layer 140a and a first gate conductive layer 150a sequentially stacked on the first semiconductor layer SL1, and the second gate G2 may include a second gate insulating layer 140b and a second gate conductive layer 150b sequentially stacked on the second semiconductor layer SL2. The first gate conductive layer 150a and the second gate conductive layer 150b may either be formed of the same material, or not. A first source S1 and a first drain D1 may be formed by doping p-type impurities with high concentration in the first semiconductor layer SL1 at both side portions of the first gate G1. A second source S2 and a second drain D2 may be formed by doping n-type impurities with high concentration in the second semiconductor layer SL2 at both side portions of the second gate G2. The first gate G1, the first source S1, and the first drain D1 constitute the PMOS transistor PT1 and the second gate G2, the second source S2, and the second drain D2 constitute the NMOS transistor NT1.

Although not shown in the drawings, after a metal layer may be formed on the first source S1, the first drain D1, the second source S2, and the second drain D2, an annealing process may be performed thereon. By performing the annealing process, dopants of the first source S1, the first drain D1, the second source S2, and the second drain D2 may be segregated to form a Schottky barrier junction. As a result, a contact resistance of the first source S1, the first drain D1, the second source S2, and the second drain D2 may be reduced.

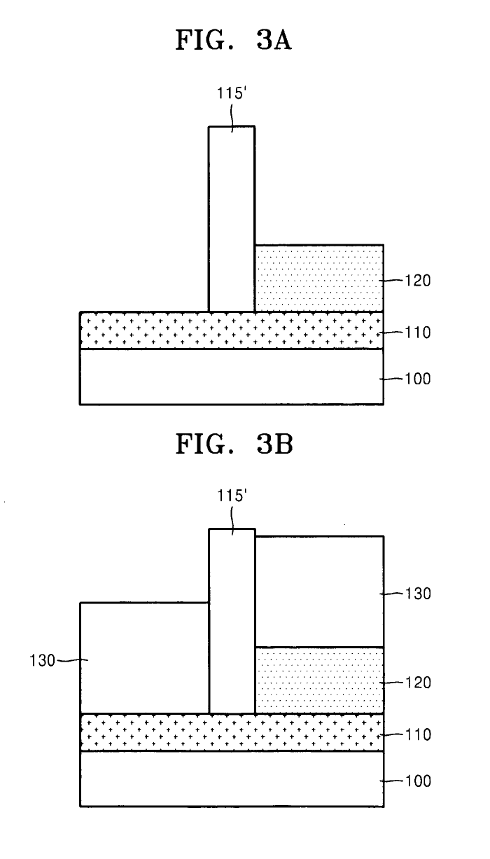

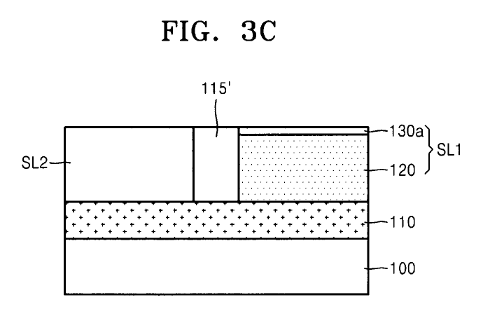

The above-described method of manufacturing the CMOS device according to example embodiments may be modified into various forms. For example, the method of manufacturing the CMOS device illustrated in FIG. 2D may be varied, and one of its variations is illustrated in FIGS. 3A through 3C.

Referring to FIG. 3A, an insulating layer 115′ may be higher than the insulating layer 115 of FIG. 2B. Other parts except for the height of the insulating layer 115′ may be substantially the same as illustrated in FIG. 2B.

Referring to FIG. 3B, a semiconductor layer 130 may be grown on the epi-layer 110 and the lower layer 120 using an epitaxial growth method.

A structure illustrated in FIG. 3C may be obtained by performing a CMP method on the semiconductor layer 130 and the insulating layer 115′. The structure of the CMOS device illustrated in FIG. 3C may be substantially the same as that of the CMOS device illustrated in FIG. 2D. The subsequent methods of manufacturing the CMOS device may be the same as the above-described methods.

According to an example embodiment, since a CMOS device may be manufactured from a Si substrate without using a wafer bonding method, a manufacturing process of the CMOS device may be simplified, and a manufacturing cost of the CMOS device may be reduced as compared to a CMOS device manufactured from another substrate such as a SOI substrate, or as compared to when a CMOS device is manufactured using a wafer bonding method. For example, a method of manufacturing a CMOS device where the second semiconductor layer SL2 and the upper layer 130a are formed of the same material, and where the layers may be grown simultaneously, that is, where the second semiconductor layer SL2 and the upper layer 130a are formed using an epitaxial growth process that may performed only once, the number of processes and/or the manufacturing cost may be reduced.

While example embodiments have been shown and described, these embodiments shall not be limiting. For example, one skilled in this art shall understand that the structure and elements of a CMOS device illustrated FIG. 1, and the method of manufacturing a CMOS device described with reference to FIGS. 2A through 2E, may be modified in various ways. For example, a second semiconductor layer SL2 and an upper layer 130a may be formed of different materials, or the layers may be individually formed at different times rather than at the same time.

Example embodiments having thus been described, it will be obvious that the same may be varied in many ways. Such variations are not to be regarded as a departure from the intended spirit and scope of example embodiments, and all such modifications as would be obvious to one skilled in the art are intended to be included within the scope of the following claims.

What is claimed is:

1. A complementary metal oxide semiconductor (CMOS) device, comprising:
an epi-layer on a substrate;
a first semiconductor layer and a second semiconductor layer on different regions of the epi-layer;
a PMOS transistor on the first semiconductor layer; and
a NMOS transistor on the second semiconductor layer.

2. The CMOS device of claim 1, wherein the epi-layer comprises a SiGe layer.

3. The CMOS device of claim 1, wherein the first semiconductor layer comprises a lower layer over the epi-layer and an upper layer over the lower layer, wherein the lower layer forms a channel and the upper layer is a capping layer.

4. The CMOS device of claim 3, wherein the lower layer comprises a compressive strained Ge layer or a compressive strained GaAs layer.

5. The CMOS device of claim 3, wherein the capping layer comprises a Si layer.

6. The CMOS device of claim 3, wherein a thickness of the capping layer is about 3 to 100 nm.

7. The CMOS device of claim 1, wherein the second semiconductor layer comprises a tensile strained Si layer.

8. A complementary metal oxide semiconductor (CMOS) device, comprising:
a first semiconductor layer and a second semiconductor layer on different regions of a substrate;
a PMOS transistor on the first semiconductor layer; and
a NMOS transistor on the second semiconductor layer, wherein the first semiconductor layer includes a lower layer in which a channel is formed and a capping layer on the lower layer, and the capping layer and the second semiconductor layer are formed of the same material.

9. The CMOS device of claim 8, further comprising:
a SiGe layer on the substrate, and the first and second semiconductor layers are on the SiGe layer.

10. The CMOS device of claim 8, wherein the lower layer comprises a compressive strained Ge layer or a compressive strained GaAs layer.

11. The CMOS device of claim 8, wherein the second semiconductor layer comprises a tensile strained Si layer.

12. The CMOS device of claim 8, wherein a thickness of the capping layer is about 3 to 100 nm.

13. A method of manufacturing a complementary metal oxide semiconductor (CMOS) device, comprising:
forming an epi-layer on a substrate;
forming a first semiconductor layer on a first region of the epi-layer;
forming a second semiconductor layer on a second region of the epi-layer;
forming a PMOS transistor on the first semiconductor layer; and
forming a NMOS transistor on the second semiconductor layer.

14. The method of claim 13, wherein the epi-layer is formed of SiGe.

15. The method of claim 13, further comprising:
forming a lower layer over the epi-layer and an upper layer over the lower layer to form the first semiconductor layer, wherein the lower layer forms a channel and the upper layer is a capping layer.

16. The method of claim 15, wherein the forming the first and second semiconductor layers on the first and second regions of the epi-layer, respectively comprises:
forming the lower layer on the first region; and
forming the capping layer on the lower layer and forming the second semiconductor layer on the second region.

17. The method of claim 15, wherein the second semiconductor layer and the capping layer are formed of the same material.

18. The method of claim 17, wherein the second semiconductor layer and the capping layer are simultaneously formed.

19. The method of claim 13, wherein the second semiconductor layer comprises a tensile strained Si layer.

20. The method of claim 17, wherein the second semiconductor layer comprises a tensile strained Si layer.

21. The method of claim 15, wherein the lower layer comprises a compressive strained Ge layer or a compressive strained GaAs layer.

22. The method of claim 15, wherein the capping layer is formed with a thickness of about 3 to 100 nm.
